(19) United States
(12) Patent Application Publication
(10) Pub. No.: US 2016/0131689 A1
(43) Pub. Date: May 12, 2016

(54) REVERBERATION CHAMBER WITH IMPROVED ELECTROMAGNETIC FIELD UNIFORMITY

(71) Applicants: CENTRE NATIONAL DE LA RECHERCHE SCIENTIFIQUE, Paris (FR); SUPELEC, Gif Sur Yvette Cedex (FR); UNIVERSITE PARIS SUD 11, Orsay (FR)

(72) Inventor: Florian MONSEF, Massy (FR)

(21) Appl. No.: 14/781,519

(22) PCT Filed: Apr. 3, 2014
(86) PCT No.: PCT/FR2014/050811

§ 371 Date: Jan. 19, 2016

(30) Foreign Application Priority Data
Apr. 3, 2013 (FR) 1353001

(51) Int. Cl. G01R 29/08

(52) U.S. Cl. CPC G01R 29/0821

(57) ABSTRACT

The reverberation chamber comprises a shielded enclosure (10) made up of a floor (11), side walls (13 to 16), and a ceiling (12), together with an antenna (2) for emitting radiofrequency waves in order to generate radiation inside the enclosure (10) at a lowest usable frequency. The chamber also comprises, inside the enclosure (10), a set (5, 6) of passive and selective elements for absorbing radiofrequencies in a defined frequency band.

### FIELD OF THE INVENTION

The present invention relates to a reverberation chamber having a shielded enclosure constituted by a floor, side walls, and a ceiling, together with a radiofrequency wave emitter antenna for generating radiation inside the enclosure at a lowest usable frequency.

### PRIOR ART

Reverberation chambers with mode stirring are electromagnetic compatibility test means that comprise a shielded enclosure forming a Faraday cage inside which an apparatus for testing is inserted. Use is made of the resonant modes of the cavity as defined by the enclosure.

A reverberation chamber thus makes it possible, among other things, to test electrical equipment in order to discover the influence that surrounding electromagnetic radiation can have on the electrical equipment, or vice versa, in order to determine the electromagnetic energy that is emitted by the electrical equipment into its environment.

Nowadays mode stirring is thus performed essentially in the microwave range for the purpose of taking measurements during electromagnetic compatibility (EMC) testing. Such means for performing tests that are carried out in a reverberation chamber are governed by an International Electrotechnical Commission (ISO) standard number 61000-4-21.

Stirring serves to ensure statistical uniformity for the field, and it is performed at a fixed frequency. The mechanical technique is based on using a mode stirrer having a rotary metal blade that serves to modify boundary conditions. The blade may be used in a stepwise mode of rotation or in a continuous mode of rotation. The purpose of the continuous mode of rotation is to accelerate the stirring procedure. Nevertheless, its speed is limited in order to ensure that conditions are steady.

A reverberation chamber can accept a minimum frequency that is referred to as the lowest usable frequency (LUF), which frequency is associated with mode overlap that is written N1 herein.

For a metal reverberation chamber of fixed dimensions, proposals have already been made for a technique enabling both the uniformity of the electromagnetic field and a reduction in the LUF to be improved locally. This requires additional antennas to be inserted that are fastened to the walls, together with the use of an arbitrary generator, which is expensive. The principle is based on synthesizing (arbitrary) signals that are injected into the various antennas. The idea is to excite modes that are usually too attenuated in a conventional configuration in order to increase artificially the number of modes that are excited, i.e. the mode overlap, thereby making it possible to obtain statistical uniformity for the electromagnetic field, including at frequencies lower than the LUF. For further details on that known technique, reference may be made to an article by Cozza et al. published in Symposium on Electromagnetic Compatibility (APEMC), 2012 Asia-Pacific, pp. 765-768 (Ref. 1).

### DEFINITION AND OBJECT OF THE INVENTION

The present invention seeks to remedy the above-mentioned drawbacks and to improve the uniformity of the electromagnetic field in a reverberation chamber, while also making it possible to reduce the lowest usable frequency of a reverberation chamber.

The invention also seeks to obtain these results with materials and components that are inexpensive.

In accordance with the invention, these objects are achieved by a reverberation chamber with improved electromagnetic field uniformity, the chamber comprising a shielded enclosure made up of a floor, side walls, and a ceiling, together with an antenna for emitting radiofrequency waves in order to generate radiation inside the enclosure at a lowest usable frequency, the chamber being characterized in that it also comprises, inside the enclosure, a set of passive and selective elements for absorbing radiofrequencies in a defined frequency band having an upper boundary that is said minimum lowest usable frequency of the reverberation chamber, and in that the passive and selective elements for radiofrequency absorption are arranged at a distance from the side walls of the enclosure that is not less than half the wavelength corresponding to said lowest usable frequency of the reverberation chamber.

The reverberation chamber includes a mode stirrer for stirring resonant modes inside the enclosure.

In more particular manner, the passive and selective radiofrequency absorption elements comprise artificial composite materials having transmission coefficient properties that are frequency selective.

In a particular embodiment, the passive and selective radiofrequency absorption elements comprise arrays of periodic structure in which the size of the individual, patterns are of the order of half the wavelength of the desired absorption frequency.

In another particular embodiment, the passive and selective radiofrequency absorption elements comprise meta-materials including matrices of patterns.

In another particular embodiment, the passive and selective radiofrequency absorption elements comprise an absorber encapsulated in stacks of periodic structure arrays or of meta-materials.

For the meta-materials, the patterns may be etched in a conductive metal material, such as copper or aluminum on a dielectric material, and they preferably present a size that is of the order of one-tenth of a wavelength corresponding to said lowest usable frequency.

In a stack, the stack may comprise two or three superposed layers and the periodic structure arrays or the meta-materials may comprise patterns constituted by circular or square rings.

Said lowest usable frequency preferably lies in the range 100 megahertz (MHz) to 18 gigahertz (GHz).

The absorber may comprise a foam that is absorbent in the microwave range, such as a urethane foam.

In a particular embodiment, the passive and selective radiofrequency absorption elements behave as lowpass filters at the scale of the frequency bands under consideration.

The passive and selective radiofrequency absorption elements may equally well constitute a bandpass spatial filter.

In the invention, a frequency selective absorber (FSA) is thus inserted in a reverberation chamber (RC), which absorber is of a type that enables losses to be inserted locally, i.e. enables losses to be inserted in a given frequency band. A direct consequence is a (local and thus selective) improvement, in mode overlap.

The increase in this mode overlap has the effect of improving the statistical uniformity of the electromagnetic (EM) field within the reverberation chamber at a given frequency.

In a preferred embodiment, and assuming that the frequency band of the frequency selective absorber has the LUF as its upper limit, inserting the frequency selective absorber makes it possible to increase mode overlap. Mode overlap N1 is then observed at a frequency lower than the conventional LUF, which means that the lowest usable frequency of the reverberation chamber has thus been reduced.

In a particular embodiment, the passive and selective radiofrequency absorption elements comprise two-dimensional structures that are not parallel to any of the faces of the reverberation chamber, which faces are constituted by the floor, the side walls, and the ceiling.

In another particular embodiment, the passive and selective radiofrequency absorption elements comprise three-dimensional structures.

Advantageously, the passive and selective radiofrequency absorption elements are arranged inside the enclosure in a central region spaced apart from the side walls and the ceiling.

### BRIEF DESCRIPTION OF THE DRAWINGS

Other characteristics and advantages of the invention appear from the following description of particular embodiments of the invention given as examples and with reference to the accompanying drawings, in which:

FIG. 1 is a diagrammatic view of a reverberation chamber of the present invention;

FIG. 2 shows an example of a frequency-selective surface with square patterns arranged periodically in such a manner as to constitute a lowpass filter, at the scale of the frequency bands under consideration;

FIG. 3 is a graph plotting a curve that illustrates the frequency response of the frequency-selective surface shown in FIG. 2;

FIG. 4 shows an example of a stack of absorbent layers behaving as a bandpass filter;

FIG. 5 shows an example of a structure of band-stop type;

FIG. 6 shows an example of a structure that is absorbent at a plurality of frequencies;

FIG. 7 is a diagrammatic view of a reverberation chamber of the present invention, analogous to FIG. 1, but with different locations for the elements that are placed inside the chamber;

FIG. 8A is a perspective view of a particular example of a three-dimensional absorbent structure; and

FIG. 8B is an exploded view of the FIG. 8A structure.

### DETAILED DESCRIPTION OF PREFERRED EMBODIMENTS

The technique proposed in the invention serves to obtain local improvement in the uniformity of the EM field with an optional and preferred possibility of lowering the LUF.

This technique presents two major advantages over the above-summarized techniques of the prior art. The first advantage is that it is purely passive, i.e. it does not require any additional generator other than the generator that is conventionally used in a reverberation chamber. The second advantage is that constitutes an item that is transportable without any constraint specific to placement within the reverberation chamber.

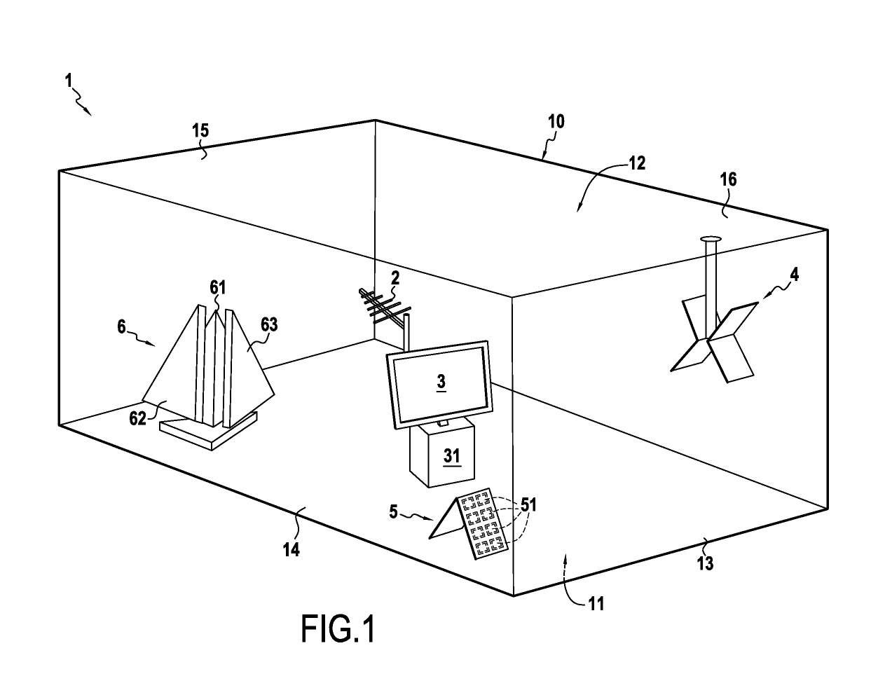

FIG. 1 shows an example of placing frequency-selective absorbers in a mode-stirring reverberation chamber 1 that comprises a shielded enclosure 10 having a floor 11, side walls 13 to 16, and a ceiling 12.

An article under test 3 is shown inside the reverberation chamber, which article may for example be a TV set or any other type of electrical or electronic apparatus that is placed on a support 31. A radio frequency wave emitter antenna 2 serves to generate radiation inside the enclosure 10 at the lowest usable frequency (LUF) for susceptibility tests. A stirrer 4 provides the desired mode stirring.

FIG. 1 also shows two passive selective absorbers 5 and 6 placed inside the enclosure 10 and obtained by two different techniques that are described below.

FIG. 7 shows another example of elements being positioned inside the reverberation chamber. Thus, in FIG. 7, there can be seen a passive selective absorber 6 that is placed in a central zone spaced apart from the lateral walls 13 to 16 and from the ceiling 12, with the absorber merely being placed on the floor 11. Likewise, a passive selective absorber 5 is also situated at a certain distance from the side walls 13 to 16. Given the small size of passive selective absorbers, the article under test 3 and the emission antenna 2 can coexist with the passive selective absorbers 5 and 6 in the central zone or at the boundaries of the central zone.

Locating the passive selective absorbers 5 and 6 at the center of the chamber 1 makes it possible to use portable structures of small dimensions. In addition, in the invention, the resonances of the chamber are not degraded excessively, thereby enabling a field intensity to be maintained that, in particular, is compatible with the IEC standard 61000-4-21.

In the invention, the low loss approximation continues to be applicable, i.e. the invention contributes firstly to improving mode overlap by means of the inserted losses (reduction in the LUF) and secondly to provide field levels that are sufficiently intense to be able to perform immunity testing on the article 3.

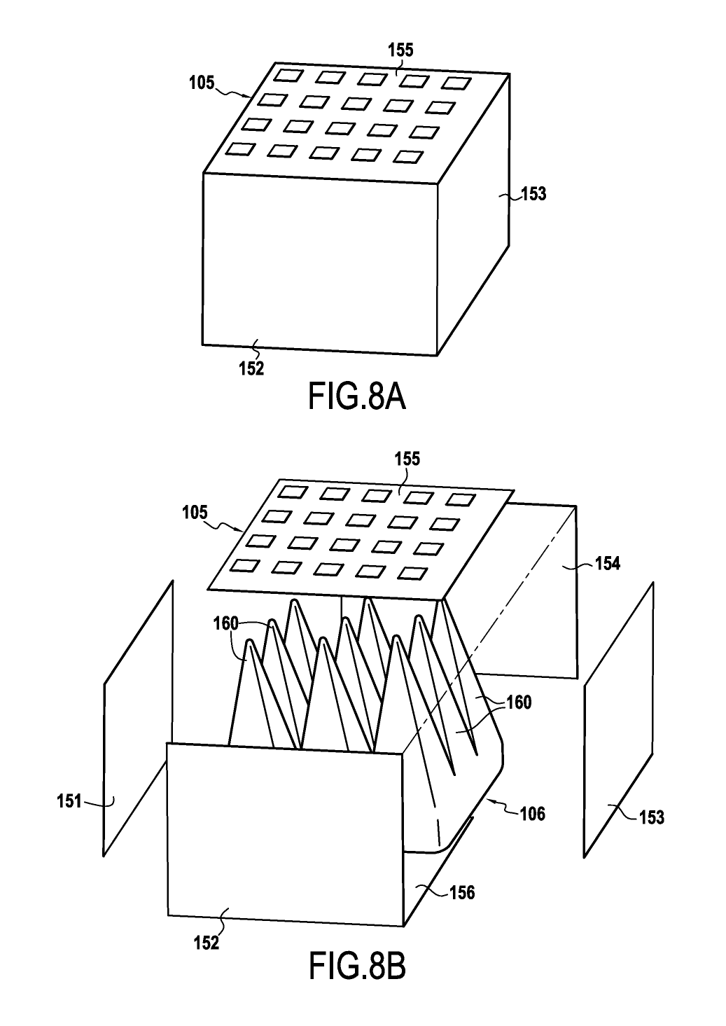

In FIGS. 1 and 7, it should be observed that two different types of passive selective absorber 5 and 6 are shown as being used simultaneously, however it is possible to perform the invention while using only one of these two types of passive selective absorber 5 or 6. It is also possible to combine these two types of passive selective absorber 5 and 6 in a single structure. A particular embodiment of combined structures is described below with reference to FIGS. 8A and 8B.

The invention is based on artificial composite materials presenting the property of a transmission coefficient that is frequently selective.

The proposal described herein is based on using arrays of conventional periodic structures, referred to as frequency-selective surfaces (FSS), and/or meta-materials. Meta-materials are also periodic structures, but they make it possible to obtain permitivities and/or permeabilities that are negative and they are generally constituted by patterns of small size, typically of λ/10 order, i.e. about one-tenth of the wavelength corresponding to the LUF. Consequently, for reasons of space occupation associated directly with the size of the patterns, it is preferable to have recourse to meta-materials for frequencies of less than GHz order.

It is important to emphasize that any other method of obtaining a frequency-selective material could be envisaged and comes within the ambit of the proposed method. Consequently, the examples described, in the present application are given by way of example and they demonstrate the feasibility of the invention, but they should not be considered as being exhaustive.

The first method proposed herein consists in considering performing the invention by using an encapsulated absorber 6.

The broadband absorber proper, referenced 61, or material A (which may be urethane for example), includes the LUF in its frequency range. The idea is to reduce the range of frequencies over which the absorbent is “seen” by EM waves.

It is important to observe that the desire to reduce this frequency range is not insignificant. It should be recalled that using a reverberation chamber involves, amongst other things, taking advantage of the resonances of the cavity 10 in order to obtain intense EM field levels that are very useful for EM susceptibility testing. Inserting losses at frequencies where mode overlap is already sufficient is therefore not beneficial insofar as the effect of resonances is reduced, thereby reducing the maximum field levels, but without that improving the uniformity of the EM field.

It can thus be understood that reducing the range is an advantage. For this purpose, one possible technique is to encapsulate the absorber 61 in elements 62, 63 that are constituted by frequency-selective surfaces (FSS) or by stacks of meta-materials presenting an overall transmission coefficient that is “flat” over a frequency band ΔF.

Each element of the stack is designed to operate over a given frequency band. The maximum size of the patterns making up the meta-material, and the maximum size of the panels of meta-material is determined to a first approximation by the LUF. Consideration should be given to a typical dimension of one-half of a wavelength for the panels and of one-tenth of a wavelength for the patterns.

By way of example, a reverberation chamber of 13 cubic meters (m³) may have an LUF around 500 MHz. It follows that panels have a size of 30 centimeters (cm) with patterns of about 6 cm. More generally, for an LUF of value fLUF, the maximum dimension lmax of a plate of polygonal type is then such that:

lmax=c/(2*fLUF)

The type of polygon is not specified herein since the exact shape of the selective surfaces is not constraining. This shape will be determined rather by the shape of the absorbers themselves.

From a phenomenological point of view, it follows that an incident wave of frequency lying within ΔF will be passed by the meta-material to the central absorber. The losses stemming from this absorber give rise to a reduction in the quality factor of the reverberation chamber at the frequency under consideration, and thus to widening of the frequency responses of the modes (included in the band ΔF) of the cavity. The effect of this widening is to be able to excite this mode over a broader frequency band. If a plurality of modes included in AT are in this situation (as indeed they are), this enables more modes to be excited at a fixed frequency than in the absence of the material B. It should be recalled that the emitter antenna in a reverberation chamber that is used in the context of the TEC standard 61000-4-21, is supposed to be excited sinusoidally, i.e. at a fixed frequency.

In contrast, if the frequency of the incident wave does not lie within ΔF, when the wave will be reflected by the meta-material and the losses of the material A are not felt. In other words, the reverberation chamber operates conventionally.

The success of the technique is further improved when the meta-materials present little anisotropy, i.e. when the behavior of the frequency-selective surfaces or of the meta-materials depends neither on the angle of incidence of the wave nor on the polarization of the wave. Such materials already exist, as indicated for example in an article by Zhou et al., Phys. Rev. Lett. 94, 243905 (Ref. 2) or indeed in an article by Huang-L. et al., Progress in Electromagnetics Research, Vol. 113, pp. 103-110, 2011 (Ref. 3).

The technique described is not exhaustive. Nevertheless, it presents a considerable advantage concerning cost since the meta-materials used in the frequency bands under consideration are basically patterns of copper 71 on a dielectric of FR4 type (a composite comprising epoxy resin reinforced with glass fibers) or of Duroid type (a composite of polytetrafluoroethylene (PTFE) reinforced with microfibers of glass).

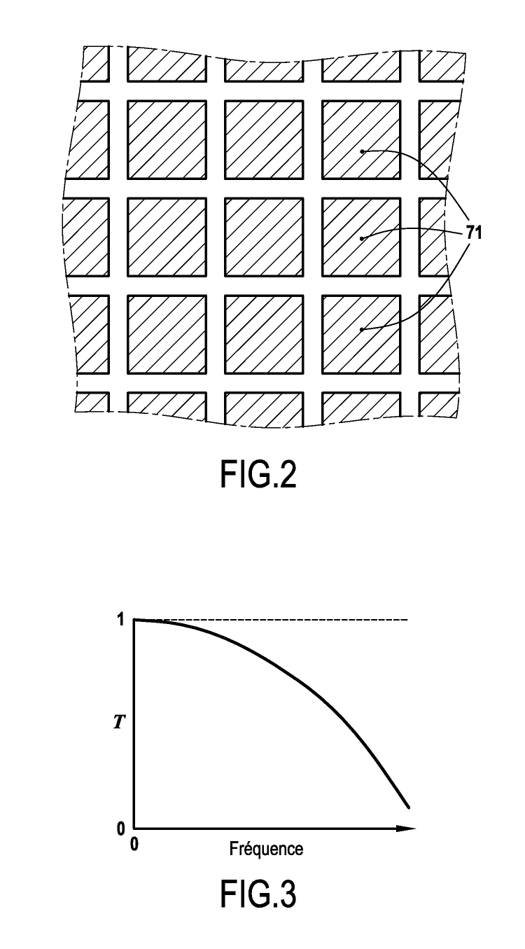

The choice of patterns and of overall structure depends on the type of filter that is desired. In order to lower the LUF, a filter of lowpass type at the scale of the preferred bands under consideration is desirable. A conventional structure then consists in using square patterns 71 that are arranged periodically, as shown in FIG. 2. The frequency response obtained by such dimensioning is shown in FIG. 3.

The advantage of the invention is not limited to possible reduction of the LUF. To understand why, certain topics are recalled below. Mode overlap depends on losses and on mode density. On average, these two quantities increase with frequency. Nevertheless, over a given frequency band, the resulting mode overlap can fluctuate very greatly. In particular at frequencies higher than the LUF, these fluctuations can give rise to EM field uniformity that is not satisfactory, or on the contrary that is very satisfactory. This disparity in scenarios is naturally that much more probable for frequency zones close to the LUF, but higher than the LOP.

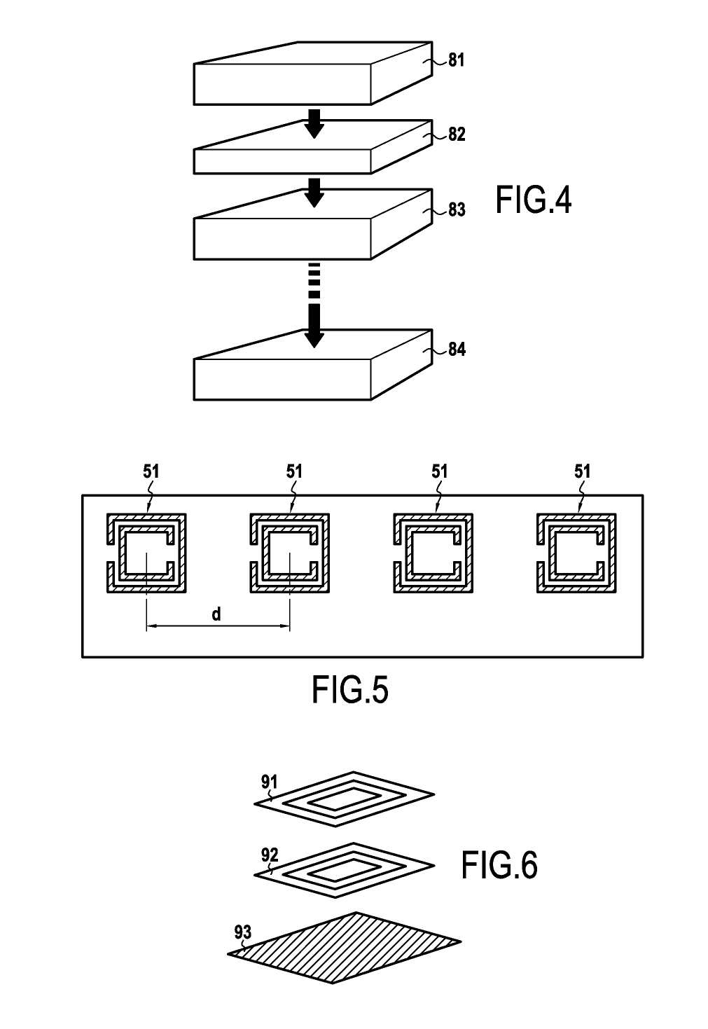

Thus, for an absorber B designed for these frequency zones, uniformity is made more probable and the reliability of test methods is therefore increased. Under such circumstances, bandpass type behavior is to be envisaged so that the absorber acts only in a defined frequency range. An example of layers 81 and 83 of material A on either side of a layer 82 of material B for the purpose of forming a bandpass spatial filter 84 is shown in FIG. 4, with the detail of how the layers are made being given in above-mentioned Ref. 3.

The second method consists in avoiding the use of an absorbent foam by using FSSs and/or meta-materials of band-stop type (cf. the article by P. Gay-Balmaz et al., J. Appl. Phys. 92 (5), pp. 2929-2936, 2002 (Ref. 4), which materials are placed directly within the reverberation chamber, as shown by element 5 in FIG. 1.

A distance of at least one-half of a wavelength is desirable between the frequency-selective absorber and the nearest vertical wall. The use of this type of device is a priori better suited for local improvement of mode density. A use for lowering the LUF is nevertheless not to be excluded. An example of such a structure is given in FIG. 5, where patterns 51 can be seen comprising two squares, one within another, and each presenting a short gap that strongly reduces the resonant frequency of the system. The centers of two successive patterns are spaced apart by a distance d. Other types of pattern can be used.

One way of dimensioning frequency-selective surfaces is described in detail in article “Frequency-selective surface and grid array” by T. K. Wu, Wiley, 1995 (Ref. 5). It should be observed that the use of frequency-selective surfaces is particularly appropriate when the frequencies at which it is desired to improve absorption are high, with this being for reasons of size. This relates typically to reverberation chambers of small size having a volume that is of the order of a few cubic meters.

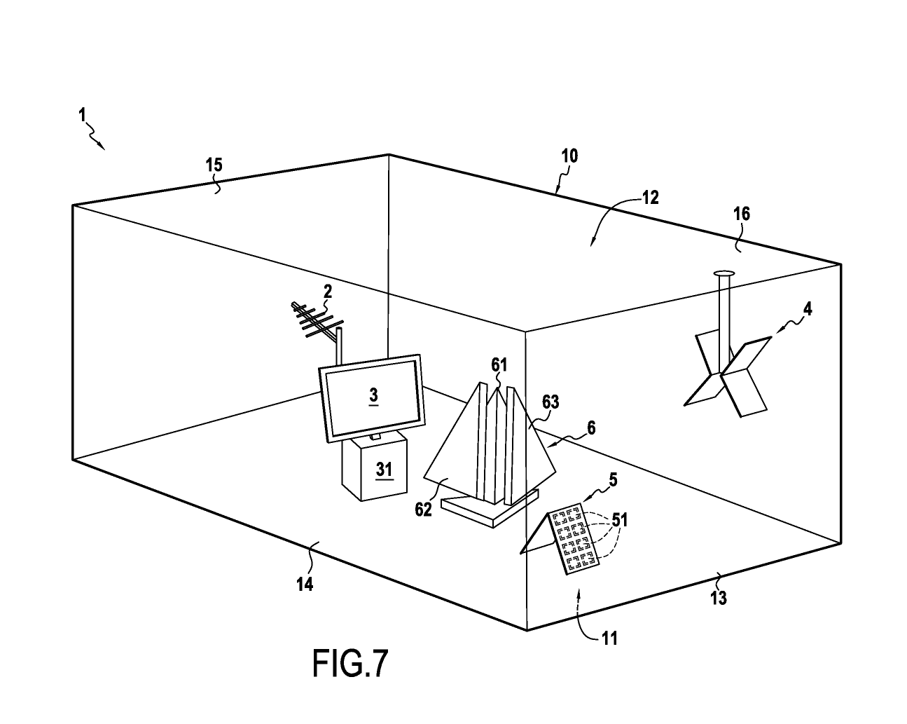

When frequencies are typically less than gigahertz order, it is preferable to use meta-materials. It may also be desirable to have absorbers at several frequencies. FIG. 6 shows an example embodiment with patterns that are superposed: a top pattern 91, a middle pattern 92, and a bottom pattern 93, with the spacing between the superposed patterns possibly being 0.5 millimeters (mm), for example. The detail of how dimensioning is performed is given in above-mentioned Ref. 3. A first layer of dielectric material is interposed between the top pattern 91 and the middle pattern 92, both made of copper and each having three concentric square rings. A second layer of dielectric material is interposed between the middle pattern 92 and the bottom pattern 93, which itself comprises a square surface filled with copper.

In general manner, the invention relates to a technique and/or to an article based on passive materials that are easily portable. In addition, the invention is based on using materials and components that are inexpensive.

Although the frequency zone close to the LUF can be used according to the standard, it involves field variances that are too great (i.e. poor field uniformity). The physics of cavities gives a very good explanation for this probability of departing from the relationship.

The present invention makes it possible to improve field uniformity in this frequency zone, thus reducing the probability of poor uniformity.

From a practical point of view, it is thus possible to envisage different off-the-shelf models. These models will have two main characteristics: the levels of losses that are inserted and the operating frequency band.

A user or a manufacturer of a reverberation chamber can acquire the model that matches the characteristics of the chamber (dimensions, loss level, value of the LUF, . . . ) firstly in order to improve the uniformity of the EM field in the sensitive zones, i.e. at frequencies greater than the LUF, and/or secondly in order to reduce the LUF.

The known “competing” technique requires antennas to be inserted in reverberation chambers, together with an arbitrary generator, which is expensive. In addition, the contribution of modes that are usually little excited means that overall efficiency is very low. The term “efficiency” is used to mean the ratio of the EM field energy within the reverberation chamber to the energy of the arbitrary signals that need to be sent to the various antennas.

For practical embodiments, the invention implies reproducibility equal to the reproducibility of present-day printed circuits with manufacturing complexity that is much less than that for present-day electronic circuit cards. An order of magnitude for the size of an absorber 5 or 6 of the invention may correspond for example to the size of a large format circuit card, i.e. 40 cm×60 cm, with a weight of no more than 1 kilogram (kg). Nevertheless, the size of encapsulated absorbers 6 depends essentially on the frequency at which it is desired to improve uniformity.

The passive and selective radiofrequency absorption elements may comprise two-dimensional structures that are not parallel to any of the faces of the reverberation chamber constituted by said floor 11, the side walls 13 to 16, and the ceiling 12 (see the elements 5 and 6 in the FIGS. 1 and 7).

The passive and selective radiofrequency absorption elements may also include three-dimensional structures, e.g. of pyramid or conical shape.

FIGS. 8A and 8B show an example of a three-dimensional structure that combines an assembly 106 of passive absorber elements 160, e.g. made of foam and possibly presenting conical shapes, with an outer box 105 having a top face 155 provided with metal patterns formed on a surface made of, dielectric material as described above, and side walls 151 to 154, and a bottom 156 that are made of metal. The plate 155 with patterns may be parallel to one of the walls (e.g. the ceiling 12) of the reverberation chamber 1, but it is in the form of a lid for the box 105 that contains a set 106 of cones 160 made of foam having dimensions that correspond to the wavelength band in which absorption is desired. In a variant, it is also possible to make an outer box 105 that is positioned in the reverberation chamber in such a manner that the plate 155 carrying patterns is not parallel to any of the walls of the reverberation chamber.

1. A reverberation chamber with improved electromagnetic field uniformity, the chamber comprising a shielded enclosure made up of a floor, side walls, and a ceiling, together with an antenna for emitting radiofrequency waves in order to generate radiation inside the enclosure at a lowest usable frequency, the chamber being characterized in that it also comprises inside the enclosure a set of passive and selective elements for absorbing radiofrequencies in a defined frequency band having an upper boundary that is said minimum lowest usable frequency of the reverberation chamber, and in that the passive and selective elements for radiofrequency absorption are arranged at a distance from the side walls of the enclosure that is not less than half the wavelength corresponding to said lowest usable frequency of the reverberation chamber.

2. A reverberation chamber according to claim 1, characterized in that it includes a mode stirrer for stirring resonant modes inside the enclosure.

3. A reverberation chamber according to claim 1, characterized in that the passive and selective radiofrequency absorption elements comprise artificial composite materials having transmission coefficient properties that are frequency selective.

4. A reverberation chamber according to claim 3, characterized in that the passive and selective radiofrequency absorption elements comprise arrays of periodic structure in which the size of the individual patterns are of the order of half the wavelength of the desired absorption frequency.

5. A reverberation chamber according to claim 3, characterized in that the passive and selective radiofrequency absorption elements comprise meta-materials including matrices of patterns.

6. A reverberation chamber according to claim 1, characterized in that the passive and selective radiofrequency absorption elements comprise an absorber encapsulated in stacks of periodic structure arrays or of meta-materials.

7. A reverberation chamber according to claim 5, characterized in that the patterns are etched in a conductive metal material on a dielectric material and present a size that is of the order of one-tenth of a wavelength corresponding to said lowest usable frequency.

8. A reverberation chamber according to claim 6, characterized in that said stack comprises two or three superposed layers and the periodic structure arrays or the meta-materials comprise patterns constituted by circular or square rings.

9. A reverberation chamber according to claim 1, characterized in that said lowest usable frequency lies in the range 100 MHz to 18 GHz.

10. A reverberation chamber according to claim 6, characterized in that the absorber comprises a foam that is absorbent in the microwave range.

11. A reverberation chamber according to claim 4, characterized in that the passive and selective radiofrequency absorption elements behave as lowpass filters at the scale of the frequency bands under consideration.

12. A reverberation chamber according to claim 1, characterized in that the passive and selective radiofrequency absorption elements constitute a bandpass spatial filter.

13. A reverberation chamber according to claim 1, characterized in that the passive and selective radiofrequency absorption elements comprise two-dimensional structures that are not parallel to any of the faces of the reverberation chamber, which faces are constituted by said floor, said side walls, and said ceiling.

14. A reverberation chamber according to claim 1, characterized in that the passive and selective radiofrequency absorption elements comprise three-dimensional structures.

15. A reverberation chamber according to claim 1, characterized in that the passive and selective radiofrequency absorption elements are arranged inside the enclosure in a central region spaced apart from said side walls and said ceiling.
